(19) United States
(12) Patent Application Publication
(10) Pub. No.: US 2010/0286939 A1
(43) Pub. Date: Nov. 11, 2010

(54) METHOD AND APPARATUS FOR DIAGNOSING DETERIORATION OF FUEL CELL

(75) Inventors: Duk-jin OH, Seoul (KR); Hee-young Sun, Yongin-si (KR)

Correspondence Address: STEIN MCEWEN, LLP, 1400 EYE STREET, NW, SUITE 300, WASHINGTON, DC, 20005, US

(73) Assignee: Samsung Electronics Co., Ltd., Suwon-si (KR)

(21) Appl. No.: 12/726,637

(22) Filed: Mar. 18, 2010

(30) Foreign Application Priority Data
May 8, 2009 (KR) 10-2009-0040464

(51) Int. Cl. G06F 19/00; G01R 27/00; G01N 27/02

(52) U.S. Cl. 702/65

(57) ABSTRACT

Provided are method and apparatus for diagnosing the deterioration of a fuel cell. The method includes: controlling a frequency of current drawn from the fuel cell; calculating an AC impedance of the fuel cell by using a pulse component of output current of the fuel cell that is generated by the control of the frequency; and diagnosing the deterioration of the fuel cell based on the calculated AC impedance.

### CROSS-REFERENCE TO RELATED APPLICATION

This application claims the benefit of Korean Patent Application No. 10-2009-0040464, filed May 8, 2009 in the Korean Intellectual Property Office, the disclosure of which is incorporated herein by reference.

### BACKGROUND

1. Field

One or more embodiments of the present invention relate to a method and apparatus for diagnosing the deterioration of a fuel cell and a fuel cell system including the apparatus for diagnosing the deterioration of a fuel cell.

2. Description of the Related Art

Fuel cells are eco-friendly alternative energy devices that generate electric energy from materials existing abundantly on earth, such as hydrogen. In general, a fuel cell has a stack structure including a plurality of cells for generating unit power. Each of the cells is formed of an anode plate, a proton exchange membrane, and a cathode plate. The anode plate is supplied with fuel, for example, hydrogen. The proton exchange membrane prevents electrons separated from hydrogen from passing and allows only protons to pass. The cathode plate is supplied oxygen from air.

However, the fuel cell deteriorates in time due to a change in the contact resistance between the cells, lack of gas supply such as hydrogen and oxygen, damage of the proton exchange membrane, and deactivation of a catalyst used to facilitate a chemical reaction in the cells. Thus, when the fuel cell is continuously used while the fuel cell deteriorates, the efficiency of the fuel cell continuously decreases or the fuel cell cannot be used anymore.

### SUMMARY

One or more embodiments of the present invention include a method and apparatus for diagnosing a fuel cell, whereby an alternating current (AC) impedance of the fuel cell is measured in a frequency range so that the fuel cell is diagnosed without using additional elements to construct a general fuel cell system or without degrading the efficiency of the fuel cell.

One or more embodiments of the present invention include a recording medium having recorded thereon a computer program for executing the method of diagnosing a fuel cell.

One or more embodiments of the present invention include a fuel cell system including the apparatus for diagnosing a fuel cell and using the method of diagnosing a fuel cell.

Additional aspects will be set forth in part in the description which follows and, in part, will be apparent from the description, or may be learned by practice of the presented embodiments.

According to one or more embodiments of the present invention, a method of diagnosing the deterioration of a fuel cell includes: controlling a frequency of a current drawn from the fuel cell; calculating an AC impedance of the fuel cell by using a pulse component of a current output from the fuel cell in response to the controlling of the frequency; and diagnosing the deterioration of the fuel cell based on the calculated AC impedance.

According to one or more embodiments of the present invention, a computer readable recording medium having embodied thereon a computer program for executing the method of diagnosing the deterioration of a fuel cell above.

According to one or more embodiments of the present invention, an apparatus for diagnosing the deterioration of a fuel cell includes: a frequency controller controlling a frequency of a current drawn from the fuel cell; an impedance calculation unit calculating an AC impedance of the fuel cell by using a pulse component of a current output from the fuel cell in response to the controlling of the frequency; and a state diagnosis unit diagnosing the deterioration of the fuel cell based on the calculated AC impedance.

According to one or more embodiments of the present invention, a fuel cell system includes: a fuel cell generating power; a controller controlling a frequency of a current drawn from the fuel cell and diagnosing the deterioration of the fuel cell by using a pulse component of a current output from the fuel cell in response to the controlling of the frequency; and a Power Conditioning System (PCS) generating power to be supplied to a load from the fuel cell.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 illustrates a fuel cell system according to an embodiment of the present invention;

FIG. 2 is a circuit diagram of a direct current (DC)/DC converter included in the fuel cell system of FIG. 1;

FIG. 3 is a flowchart illustrating a method of diagnosing the deterioration of a fuel cell according to an embodiment of the present invention;

FIG. 4 illustrates a fuel cell system according to another embodiment of the present invention; and

FIG. 5 is a flowchart illustrating a method of diagnosing the deterioration of a fuel cell according to another embodiment of the present invention.

### DETAILED DESCRIPTION

Reference will now be made in detail to the present embodiments of the present invention, examples of which are illustrated in the accompanying drawings, wherein like reference numerals refer to the like elements throughout. The embodiments are described below in order to explain the present invention by referring to the figures.

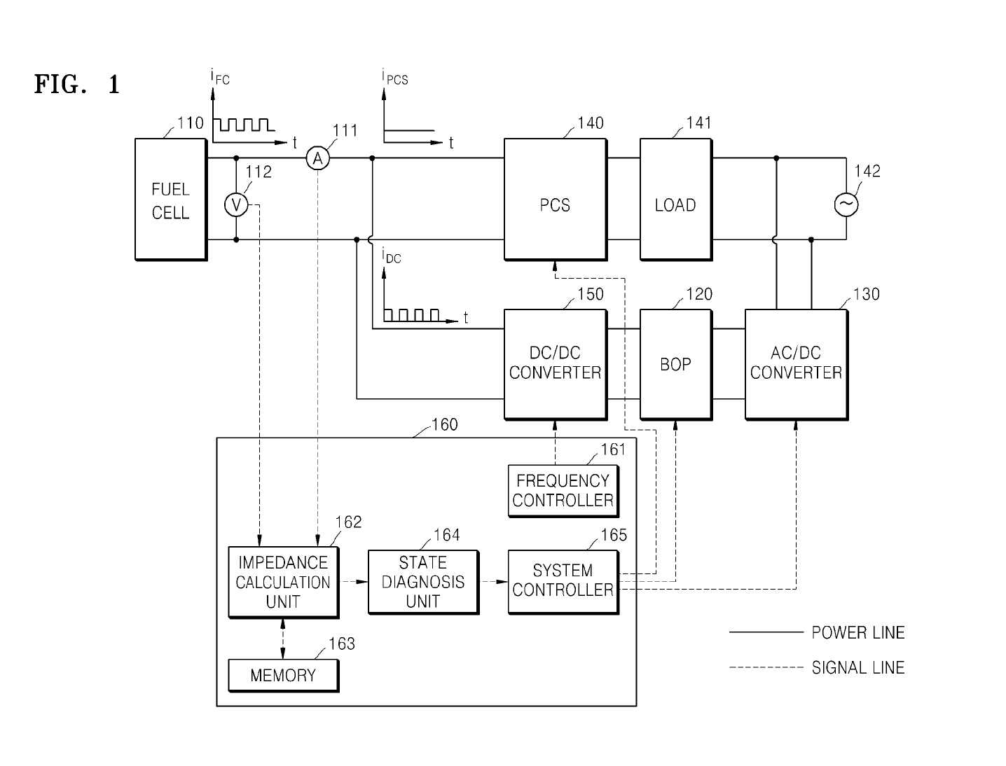

FIG. 1 illustrates a fuel cell system according to an embodiment of the present invention. Referring to FIG. 1, the fuel cell system includes a fuel cell 110, a current meter 111, a voltage meter 112, a Balance Of Plant (BOP) 120, an alternating current (AC)/direct current (DC) converter 130, a Power Conditioning System (PCS) 140, a DC/DC converter 150, and a controller 160. The fuel cell 110 is a power generating device that directly converts chemical energy of a fuel into electric energy via an electrochemical reaction. Examples of the fuel cell 110 may include a Solid Oxide Fuel Cell (SOFC), a Polymer Electrolyte Membrane Fuel Cell (PEMFC), and a Direct Methanol Fuel Cell (DMFC).

The fuel cell 110 has a stack structure including a plurality of cells generating unit power. The cells are connected to each other in series in order to obtain a high voltage or connected in parallel in order to obtain a high current. Accordingly, the current and voltage outputted from the fuel cell 110 is the current and voltage outputted from the stack of cells. Hereinafter, the current and voltage outputted from the stack of the fuel cell 110 are illustrated as the current and voltage outputted from the fuel cell 110. In addition, it would be obvious to one of ordinary skill in the art to use cells that generate DC power, instead of the fuel cell above.

The BOP 120 is a peripheral device for operating the fuel cell 110 by using the controller 160. The BOP 120 includes a pump for supplying fuel (for example, hydrogen) to the fuel cell 110, a pump for supplying an oxidizing agent for oxidizing the fuel (for example, air and oxygen) and a pump for supplying coolant. When the DC/DC converter 150 does not operate, the BOP 120 may be driven by using power supplied from the outside through a power grid 142 or by using power supplied from a separate battery or a high-capacity capacitor (not illustrated) in the fuel cell system of FIG. 1. The former case is used in a distributed generation system which collects power from fuel cells or solar cells through the power grid 142 and supplying the collected power to the load 141. The latter case is used in a stand-alone system which supplies power from one fuel cell to the load 141. When the shown DC/DC converter 150 starts operating, the BOP 120 is driven by using power supplied from the DC/DC converter 150, however, the invention is not limited thereto.

The AC/DC converter 130 converts AC power collected from the outside through the power grid 142 under the control of the controller 160 into DC power to be supplied to the BOP 120. As shown, the power grid 142 is also connected to the load 141, but need not be so connected in all aspects. Further, the AC/DC converter 130 need not be used in all aspects, which as where the outside power is a DC power source.

The PCS 140 generates AC power to be supplied to a load 141 from DC power generated by the fuel cell 110 under the control of the controller 160. For example, the PCS 140 includes a DC/DC converter and an inverter, and the DC/DC converter converts an output voltage of the fuel cell 110 to a voltage required by the load 141 and the inverter converts DC power into AC power. The DC/DC converter 150 converts an output voltage of the fuel cell 110 into a voltage to be supplied to the BOP 120 under the control of the controller 160. In order to diagnose the deterioration of the fuel cell 110 in a frequency range, the DC/DC converter 150 according to the shown embodiment draws a current from the fuel cell 110 according to the frequency input from the controller 160 and changes a voltage of the current to a voltage to be supplied to the BOP 120. Here, the current drawn i_{DC} from the fuel cell 110 has a wave form.

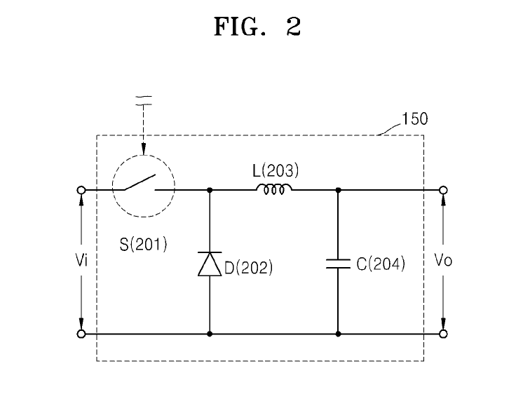

FIG. 2 is a circuit diagram of the DC/DC converter 150 included in the fuel cell system of FIG. 1. Referring to FIG. 2, the DC/DC converter 150 includes a switch 201, a diode 202, an inductor 203, and a capacitor 204. The shown DC/DC converter 150 is a type of buck converter which drops an input voltage. The buck converter is well known to one of ordinary skill in the art to which the present invention pertains and thus detailed description thereof is omitted. While shown as a buck converter, it is understood that other types of DC/DC converters 150 such as a boost converter, could be used instead of the buck converter illustrated in FIG. 2.

The ratio of the input voltage to output voltage in the ideal buck converter is Vo/Vi=D The ratio D denotes a fraction of the period of the switch 201 is turned on with respect to the entire period of the switch 201 is turned on/off and is also referred to as a duty cycle. That is, D is 0 when the switch 201 is always turned off, and D is 1 when the switch 201 is always turned on. When the switch 201 is in another state, D is between 0 and 1. The switch 201 of the DC/DC converter 150 may be a Field Effect Transistor (FET) that has high-speed switching. When no control signal is input from the controller 160 to the switch 201 of the DC/DC converter 150, the switch 201 is turned off and when a pulse type control signal is input from the controller 160 to the switch 201 of the DC/DC converter 150, the switch 201 is repeatedly turned on and off according to the control signal.

The controller 160 controls operations of the BOP 120, the AC/DC converter 130, the DC/DC converter 150, and the PCS 140 in order to control power generation of the fuel cell 110. The controller 160 according to the shown embodiment controls the frequency of current i_{DC} drawn from the fuel cell 110 by the DC/DC converter 150 and diagnoses deterioration of the fuel cell 110 by using a component of the current I_{FC} output by the fuel cell 110.

By way of example, the controller 160 controls the switching of the switch 201 in the DC/DC converter 150 by using Pulse Frequency Modulation (PFM) in order to draw the pulse-form current i_{DC} from the fuel cell 110 via the DC/DC converter 150, and the frequency of the pulse-form current i_{DC} is controlled by the controller 160. That is, the controller 160 drives the DC/DC converter 150 by controlling the switching frequency of the switch 201 of the DC/DC converter 150.

In general, when a pulse-form control signal having a high frequency is input to the switch 201 of the DC/DC converter 150 from the controller 160, the duty cycle D of the switch 201 of the DC/DC converter 150 increases. As a result, the DC/DC converter 150 outputs a high voltage. When a pulse-form control signal having a low frequency is input to the switch 201 of the DC/DC converter 150 from the controller 160, the duty cycle D of the switch 201 of the DC/DC converter 150 decreases. As a result, the DC/DC converter 150 outputs a low voltage. In this case, it is assumed that a high period is constant regardless of the frequency of the control signal output from the controller 160. In the shown embodiment, the high period of the pulse decreases at high frequency and a high period of the pulse increases at low frequency so that the duty cycle D of the switch 201 in the DC/DC converter 150 may be maintained constant. Accordingly, although the switching frequency of the switch 201 in the DC/DC converter 150 changes, the output voltage of the DC/DC converter 150 may be constant.

Also, the controller 160 controls the switching of the switch of the DC/DC converter in the PCS 140 by using Pulse Width Modulation (PWM) in order to draw a direct-current i_{pcs} from the fuel cell 110. That is, the controller 160 controls the width of switching on or off of the switch of the DC/DC converter in the PCS 140 and thus drives the DC/DC converter 150. In general, when a pulse control signal in which a high period is wider than a low period is input to the switch 201 of the DC/DC converter 150 from the controller 160, the duty cycle D of the switch 201 in the DC/DC converter 150 increases and as a result, the DC/DC converter 150 outputs a high voltage. When a pulse control signal of which a low period is wider than a high period is input to the switch 201 of the DC/DC converter 150 from the controller 160, the duty cycle D of the switch 201 in the DC/DC converter 150 decreases and as a result, the DC/DC converter 150 outputs a low voltage.

Referring to FIG. 1, the shown controller 160 includes a frequency controller 161, an impedance calculation unit 162, a memory 163, a state diagnosis unit 164, and a system controller 165. While not required in all aspects, it is understood that the controller 160 and/or the system controller 165 can be one or more processors implementing instructions encoded using software and/or firmware on a computer readable recording medium, such as the memory 163. Further, the memory 163 can be detachable from the controller 160 or connected to the controller 160 across a network, and can be magnetic and/or optical storage media in other aspects of the invention.

The frequency controller 161 controls the switching frequency of the switch 201 of the DC/DC converter 150 and thus controls the frequency of the pulse-form current I_{DC} drawn from the fuel cell 110. When the switch 201 of the DC/DC converter 150 is on according to the pulse-form control signal input from the frequency controller 161, current I_{DC} is drawn from the fuel cell 110 to the DC/DC converter 150 and when the switch 201 of the DC/DC converter 150 is off, no current I_{DC} is drawn to the DC/DC converter 150. As a result, an interim current I_{DC} flows through a connection line between the fuel cell 110 and the DC/DC converter 150. The interim current I_{DC} is a current that is similar to square wave-form current.

The impedance calculation unit 162 calculates an alternating current (AC) impedance of the fuel cell 110 by using a pulse component of the current I_{FC} output by the fuel cell 110 in response to the frequency control of the frequency controller 161. For example, the impedance calculation unit 162 Fast Fourier Transforms a current value measured by the current meter 111 and a voltage value measured by the voltage meter 112 and thus extracts a pulse component (which is a kind of frequency component) from the current value and the voltage value. The extracted pulse component is used to calculate the AC impedance of the fuel cell 110. The AC impedance may be also referred to as a complex impedance.

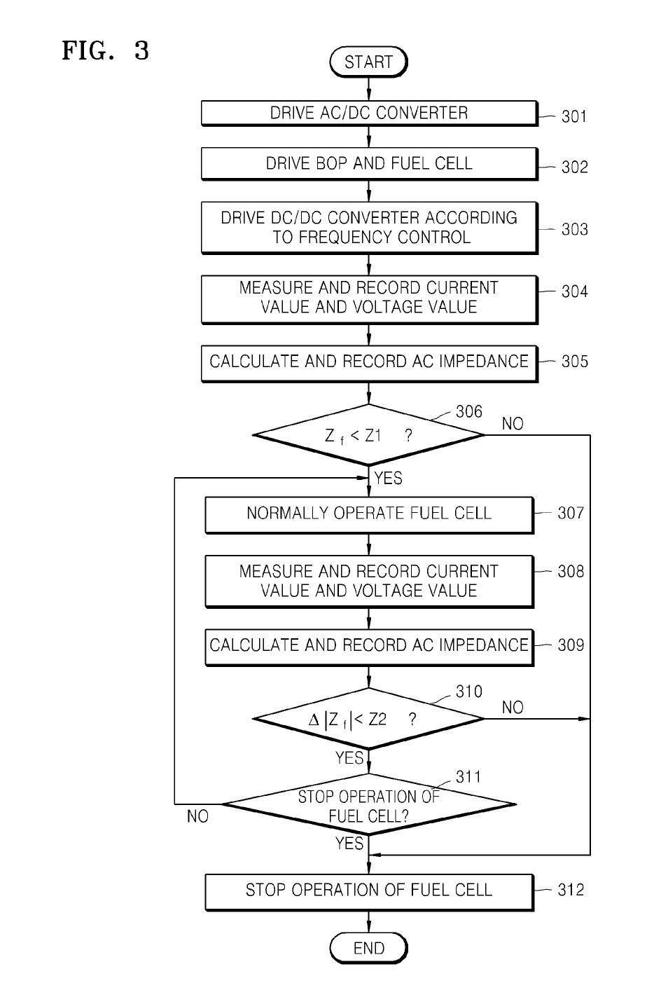

The state diagnosis unit 164 diagnoses the deterioration of the fuel cell 110 based on the AC impedance of the fuel cell 110 calculated by the impedance calculation unit 162. The system controller 165 controls the operation of the BOP 120, the AC/DC converter 130, the DC/DC converter 150, and the PCS 140 according to the deterioration state of the fuel cell 110 diagnosed by the state diagnosis unit 164. As described above, the AC impedance of the fuel cell 110 is calculated by using the pulse component of the current I_{FC} output by the fuel cell 110 by controlling the frequency of the current i_{DC} drawn from the fuel cell 110 so that the AC impedance of the fuel cell 110 may be measured without adding new parts for calculating the AC impedance of the fuel cell 110 to the fuel cell system or damaging the efficiency of the fuel cell system. In addition, the AC impedance of the fuel cell 110 is calculated at a constant frequency at which deterioration of the fuel cell 110 is easily diagnosed, and thus accuracy of the deterioration diagnosis of the fuel cell 110 may be improved. Hereinafter, the operation of the controller 160 is described in more detail with reference to FIG. 3.

FIG. 3 is a flowchart illustrating a method of diagnosing the deterioration of the fuel cell 110 according to an embodiment of the present invention. Referring to FIG. 3, the method of diagnosing the deterioration of the fuel cell 110 includes the following operations processed in time series in the controller 160 illustrated in FIG. 1. Accordingly, although the description illustrated above with regard to the fuel cell system of FIG. 1 is omitted below, the description is applied to the method of diagnosing the deterioration of the fuel cell 110 according to the present embodiment.

In operation 301, the system controller 165 drives the AC/DC converter 130. Accordingly, the AC/DC converter 130 converts AC power collected from the outside through the power grid 142 into DC power to be applied to the BOP 120. In operation 302, the system controller 165 drives the BOP 120. Accordingly, the BOP 120 drives the fuel cell 110 by using the DC power outputted from the AC/DC converter 130 and the fuel cell 110 generates DC power. However, it is understood that the AC/DC converter 130 need not be used where the power is supplied from a DC source, such as a battery.

In operation 303, the frequency controller 161 drives the DC/DC converter 150. For example, the frequency controller 161 controls the switching frequency of the switch 201 in the DC/DC converter 150 and thus controls the frequency of the current i_{DC} drawn from the fuel cell 110. Accordingly, the DC/DC converter 150 draws current from the fuel cell 110 according to the frequency controlled by the controller 160 and a voltage of the drawn current i_{DC} is converted into a voltage to be applied to the BOP 120. For example, the frequency controller 161 changes the switching frequency of the switch 201 in the DC/DC converter 150 at a specific frequency range. The specific frequency range denotes a frequency range where the deterioration state of the fuel cell 110 is best represented. The frequency range may vary according to the characteristics of the fuel cell 110 and peripheral devices around the fuel cell 110.

In operation 304, the impedance calculation unit 162 records the current value measured by the current meter 111 and a voltage value measured by voltage meter 112 in the specific frequency range to the memory 163. For example, the impedance calculation unit 162 reads the current value and voltage value respectively from the current meter 111 and the voltage meter 112 in each frequency in the specific frequency range and records the read current value and voltage value to the memory 163. The specific frequency may be one specific frequency, various specific frequencies, or frequencies at constant intervals according to the method of diagnosing the deterioration of the fuel cell 110. In operation 305, the impedance calculation unit 162 calculates the AC impedance Z_{f} of the fuel cell 110 by using the current value and voltage value recorded to the memory 163 in operation 304 and the calculated AC impedance Z_{f} is recorded to the memory 163.

In operation 306, the state diagnosis unit 164 compares the AC impedance Z_{f} of the fuel cell 110 recorded to the memory 163 in operation 305 with a threshold value Z₁ used to diagnose the deterioration of the fuel cell 110 in no-load running. For example, the state diagnosis unit 164 may compare an absolute value or a real number component of the AC impedance Z_{f} of the fuel cell 110 corresponding to one specific frequency with the threshold value Z₁. Alternatively, the state diagnosis unit 164 may compare a combination value of the absolute value or the real number components of the AC impedance Z_{f} of the fuel cell 110 respectively corresponding to various specific frequencies with the threshold value Z₁. Alternatively, the state diagnosis unit 164 determines the frequency at which an imaginary number component is 0 through a frequency sweep on a frequency characteristic curve representing the relationship between the real number component and the imaginary number component of the AC impedances Z_{f} of the fuel cell 110 corresponding to the frequencies at constant intervals and may compare the real number component at the frequency with the threshold value Z₁.

According to other aspects of the invention, other approaches can be used in addition to or instead of the above-described method of diagnosing the deterioration of fuel cell 110. As a result of the comparison, when the AC impedance of the fuel cell 110 is smaller than the threshold value Z₁, it is diagnosed that the fuel cell 110 is not deteriorated and operation 307 is performed. When the AC impedance Z_{f} of the fuel cell 110 is not smaller than the threshold value Z₁, it is diagnosed that the fuel cell 110 is deteriorated and operation 312 is performed. When the AC impedance Z_{f} of the fuel cell 110 is unusually great, it is represented that the fuel cell 110 is deteriorated.

As described above, the deterioration of the fuel cell 110 is diagnosed in a no-load running state before the PCS 140 which generates power to be supplied to a load is driven so that deterioration of the fuel cell 110 may be accurately diagnosed. In operation 307, the system controller 165 drives the PCS 140 and thus the fuel cell 110 is normally operated when the impedance Z_{f} is less than the threshold value Z₁. Accordingly, the PCS 140 generates AC power to be supplied to the load 141 from the DC power generated by the fuel cell 110. Due to the normal operation, power is supplied to the load 141 from the fuel cell system of FIG. 1.

In operation 308, the impedance calculation unit 162 records the current value measured by the current meter 111 and voltage value measured by the voltage meter 112 in the specific frequency range, as in operation 304, to the memory 163. In operation 309, as in operation 305, the impedance calculation unit 162 calculates the AC impedance Z_{f} of the fuel cell 110 by using the current value and voltage value recorded to the memory 163 in operation 308 and the calculated AC impedance is recorded to the memory 163. Operations 308 and 309 are repeated at sampling intervals for a fixed period of time. In order to minutely diagnose the deterioration of the fuel cell 110, the sampling intervals are narrowed and thus the controller 160 may continuously measure the AC impedance of the fuel cell 110. Also, in order to reduce a calculation amount for diagnosing the deterioration of the fuel cell 110, the sampling intervals are expanded and thus the controller 160 may periodically measure the AC impedance of the fuel cell 110. Appropriate sampling intervals may be selected in consideration of performance of hardware of the controller 160.

In operation 310, the state diagnosis unit 164 compares a change amount of the AC impedance Z_{f} of the fuel cell 110 calculated during the fixed time in operation 309 with a threshold value Z₂ used to diagnose deterioration of the fuel cell 110 in an arbitrary load running condition. The arbitrary load running condition denotes running of the fuel cell 110 in a load arbitrarily set by a user. As a result of the comparison, when the change amount of the AC impedance of the fuel cell 110 is smaller than the threshold value Z₂, it is diagnosed that the fuel cell 110 is deteriorated and operation 311 is performed. When the change amount of the AC impedance of the fuel cell 110 is not smaller than the threshold value Z₂, it is diagnosed that the fuel cell 110 is not deteriorated and operation 311 is performed. When the change amount of the AC impedance Z_{f} of the fuel cell 110 is unusually great, it is considered that the fuel cell 110 is deteriorated.

In operation 311, the system controller 165 checks for the reception of a command for stopping the operation of the fuel cell 110 from a user. As a result, when the command for stopping the operation of the fuel cell 110 is received from the user, the operation 312 is performed. When the command for stopping the operation of the fuel cell 110 is not received from the user, the operation 307 is performed. In operation 312, the system controller 165 stops the operation of the fuel cell 110. The controller 160 stops the operation of the BOP 120 by blocking supply of fuel or air to the BOP 120 or by blocking power supply to the DC/DC converter 150. The operation of the fuel cell 110 is stopped according to the diagnosis result for the deterioration of the fuel cell 110 so that the fuel cell 110 may be protected. Accordingly, the fuel cell 110 may be prevented from breaking down or the life span of the fuel cell 110 may be extended. While shown, it is understood that operation 311 need not be performed in all aspects, such as where the controller 160 automatically stops operation of the fuel cell 110 without user intervention.

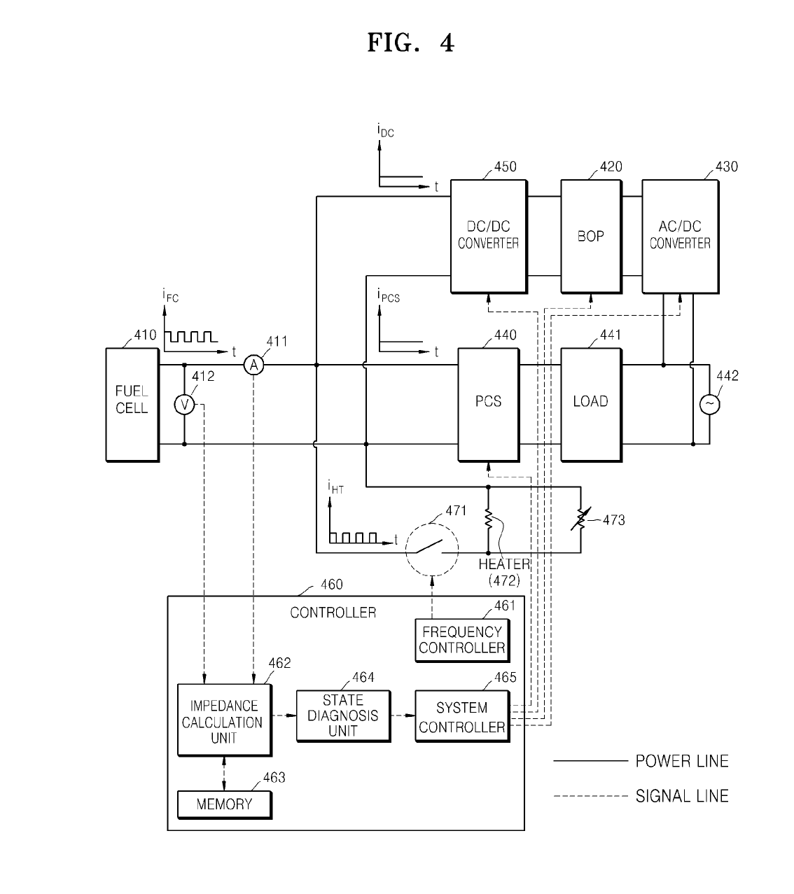

FIG. 4 illustrates a fuel cell system according to another embodiment of the present invention. Referring to FIG. 4, the fuel cell system includes a fuel cell 410, a current meter 411, a voltage meter 412, a BOP 420, an AC/DC converter 430, a PCS 440, a DC/DC converter 450, a controller 460, a switch 471, a heater 472, and variable resistance 473. The fuel cell system of FIG. 4 further includes the switch 471, the heater 472, and the variable resistance 473, in comparison to the fuel cell system of FIG. 1. Hereinafter, the fuel cell system of FIG. 4 is described based on the differences from the fuel cell system of FIG. 1. Accordingly, except for the description provided below, the description of the fuel cell system of FIG. 1 is applied to the fuel cell system of FIG. 4.

Unlike the DC/DC converter 150 of FIG. 1, the DC/DC converter 450 draws a direct current form from the fuel cell 410 and a voltage of the current is changed to a voltage to be applied to the BOP 420. In order to draw the direct current i_{DC} from the fuel cell 410 by the DC/DC converter 450, the controller 460 controls the switching of the switch of the DC/DC converter 450 by using the PWM as in the PCS 440. The switch of the DC/DC converter 450 may be the same as the switch 201 of FIG. 2.

The heater 472 generates heat powering response to the direct current drawn i_{HT} from the fuel cell 410 according to the control of the controller 460. The heat generated from the heater 472 is used in heating a housing where the fuel cell system of FIG. 4 is installed. Additionally, the heater 472 draws a current i_{HT} from the fuel cell 410 according to the frequency input from the controller 460 in order to diagnose the deterioration of the fuel cell 410 at a specific frequency range and the current is used to generate heat.

In order to control heat generation of the heater 472, the controller 460 controls the operation of the switch 471 that is connected to the heater 472. For example, in order to draw the current i_{HT} of which frequency is controlled by the controller 460 from the fuel cell 410 by the heater 472, the controller 460 controls switching of the switch 471 of the heater 472 by using PFM. That is, the controller 460 controls the switching frequency of the switch 471 that is connected to the heater 472 and thus drives the heater 472.

In general, when a pulse control signal having a high frequency is input to the switch 471 that is connected to the heater 472 from the controller 460, the duty cycle D of the switch 471 increases, and as a result, the heater 472 generates heat having a high temperature. When a pulse control signal having a low frequency is input to the switch 471 that is connected to the heater 472 from the controller 460, the duty cycle D of the switch 471 decreases, and as a result, the heater 472 generates heat having a low temperature. In this case, it is assumed that a high period is constant regardless of the frequency of the control signal output from the controller 460. In the shown embodiment, the high period of the pulse decreases at a high frequency and the high period of the pulse increases at a low frequency so that the duty cycle D of the switch 471 that is connected to the heater 472 may be constant. Accordingly, although the switching frequency of the switch 471 that is connected to the heater 472 changes, the temperature of the heat generated by the heater 472 may be constant.

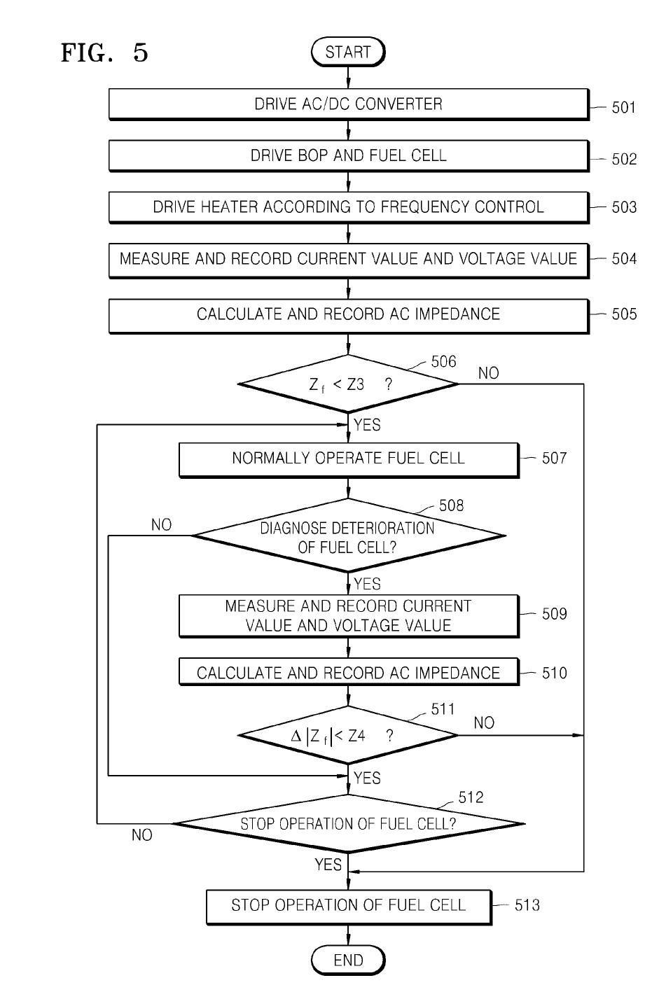

Referring to FIG. 4, like in the fuel cell system of FIG. 1, the controller 460 includes a frequency controller 461, an impedance calculation unit 462, a memory 463, a state diagnosis unit 464, and a system controller 465. The frequency controller 461 controls the switching frequency of the switch 471 that is connected to the heater 472, and thus controls the frequency of the pulse-type current i_{HT} drawn from the fuel cell 410. Hereinafter, the operation of the controller 460 is described in more detail with reference to FIG. 5.

FIG. 5 is a flowchart illustrating a method of diagnosing the deterioration of the fuel cell 410 according to another embodiment of the present invention. Referring to FIG. 5, the method of diagnosing the deterioration of the fuel cell 410 includes the following operations processed in time series in the controller 460 illustrated in FIG. 4. Accordingly, although the description illustrated above with regard to the fuel cell system of FIG. 4 is omitted below, the description is also applied to the method of diagnosing the deterioration of the fuel cell 410 according to the present embodiment.

In operation 501, the system controller 465 drives the AC/DC converter 430. Accordingly, the AC/DC converter 430 converts AC power collected from the outside through a power grid 442 into DC power to be applied to the BOP 420. In operation 302, the system controller 165 drives the BOP 120. Accordingly, the BOP 420 drives the fuel cell 410 by using the DC power outputted from the AC/DC converter 430 and the fuel cell 410 generates the DC power.

In operation 503, the frequency controller 461 drives the heater 472. For example, the frequency controller 461 controls the switching frequency of the switch 471 that is connected to the heater 472, and thus controls the frequency of the current i_{HT} drawn from the fuel cell 410. Accordingly, the heater 472 draws the current from the fuel cell 410 according to the frequency controlled by the controller 460 and the current i_{HT} is used to generate heat. For example, the frequency controller 461 changes the switching frequency of the switch 471 that is connected to the heater 472 to a specific frequency range. The specific frequency range denotes a frequency range where the deterioration state of the fuel cell 410 is well represented. The frequency range may vary according to characteristics of the fuel cell 410 and peripheral devices around the fuel cell 410.

In operation 504, the impedance calculation unit 462 records the current value measured by the current meter 411 and voltage value measured by voltage meter 412 in the specific frequency range to the memory 463. For example, the impedance calculation unit 462 reads the current value and voltage value respectively from the current meter 411 and the voltage meter 412 at each specific frequency of the specific frequency range and records the read current value and voltage value to the memory 463. The each specific frequency may be one specific frequency, various specific frequencies, or frequencies at constant intervals according to the method of diagnosing the deterioration of the fuel cell 410. In operation 505, the impedance calculation unit 462 calculates the AC impedance Z_{f} of the fuel cell 410 by using the current value and voltage value recorded to the memory 463 in operation 504 and the calculated AC impedance is recorded to the memory 463.

In operation 506, the state diagnosis unit 464 compares the AC impedance Z_{f} of the fuel cell 410 recorded to the memory 463 in operation 505 with a threshold value Z₃ used to diagnose the deterioration of the fuel cell 410 in regular load running. The regular load running denotes running of the fuel cell 410 in a regular load set by a user. For example, in order to accurately correct a load value desired by the user, the variable resistance 473 may be additionally connected to the heater 472. Accordingly, a value of the variable resistance 473 of the heater 472 may be adjusted until the load value desired by the user is obtained. Comparative examples of the AC impedance Z_{f} by the state diagnosis unit 464 and the threshold value Z₃ are the same as in operation 306 of FIG. 3 and thus detailed description thereof is omitted. As a result of the comparison, when the AC impedance Z_{f} of the fuel cell 410 is smaller than the threshold value Z₃, it is diagnosed that the fuel cell 410 is not deteriorated and operation 507 is performed. When the AC impedance Z_{f} of the fuel cell 410 is not smaller than the threshold value Z₃, it is diagnosed that the fuel cell 410 is deteriorated and operation 513 is performed. As described above, the deterioration of the fuel cell 410 is diagnosed in regular load running, where the deterioration of the fuel cell 410 is easily diagnosed, before the PCS 140, which generates power to be supplied to the load, is driven so that deterioration of the fuel cell 410 may be accurately measured.

In operation 507, the system controller 465 drives the DC/DC converter 450 and the PCS 440 and thus the fuel cell 410 is normally operated. Accordingly, the DC/DC converter 450 converts the output voltage of the fuel cell 410 into a voltage to be supplied to the BOP 420 and the PCS 440 generates AC power to be supplied to the load 441 from the DC power generated by the fuel cell 410. Due to the normal operation, power is supplied to the load 441 from the fuel cell system of FIG. 4.

In operation 508, the system controller 465 checks for the reception of a command for requesting deterioration diagnosis of the fuel cell 410 from a user. As a result, when the command for requesting deterioration diagnosis of the fuel cell 410 is received from the user, the operation 509 is performed. When the command for requesting deterioration diagnosis of the fuel cell 410 is not received from the user, the operation 512 is performed. While described in terms of a command from the user, it is understood that the request can be automatically generated and need not be input by a user in all aspects. Further, if the deterioration is always to be monitored, operation 508 need not be performed.

In operation 509, the impedance calculation unit 462 records the current value measured by the current meter 411 and voltage value measured by the voltage meter 412 in the specific frequency range, as in operation 504, to the memory 463. In operation 510, as in operation 505, the impedance calculation unit 462 calculates the AC impedance of the fuel cell 410 by using the current value and voltage value recorded to the memory 463 in operation 509 and the calculated AC impedance is recorded to the memory 463. Operations 509 and 510 are repeated at sampling intervals for a fixed period of time. Setting of the sampling intervals is the same as in operations 309 and 319 of FIG. 3 and thus detailed description thereof is omitted.

In operation 511, the state diagnosis unit 464 compares a change amount of the AC impedance Z_{f} of the fuel cell 410 calculated during the fixed time in operation 510 with a threshold value Z₄ used to diagnose deterioration of the fuel cell 410 in an arbitrary load running. The arbitrary load running denotes running of the fuel cell 410 in a load arbitrarily set by a user. As a result of the comparison, when the change amount of the AC impedance Z_{f} of the fuel cell 410 is smaller than the threshold value Z₄, it is diagnosed that the fuel cell 410 is deteriorated and operation 512 is performed. When the change amount of the AC impedance Z_{f} of the fuel cell 410 is not smaller than the threshold value Z₄, it is diagnosed that the fuel cell 410 is not deteriorated and operation 513 is performed.

In operation 512, the system controller 465 checks for the reception of a command for stopping the operation of the fuel cell 410 from a user. As a result, when the command for stopping the operation of the fuel cell 410 is received from the user, the operation 513 is performed. When the command for stopping the operation of the fuel cell 410 is not received from the user, the operation 507 is performed. While described in terms of a command from the user, it is understood that the request can be automatically generated and need not be input by a user in all aspects. Further, if the fuel cell 410 is always to be stopped when the deterioration is detected, operation 512 need not be performed.

In operation 513, the system controller 465 stops the operation of the fuel cell 410. The controller 460 stops the operation of the BOP 420 by blocking supply of fuel or air of the BOP 420 or blocking power supply to the DC/DC converter 450 and thus may stop the operation of the fuel cell 410.

According to one or more embodiments described above, the AC impedance of the fuel cell is calculated by using the pulse component of the current output from the fuel cell that in response to the control of the frequency of the current drawn from the fuel cell. Thus, the AC impedance of the fuel cell may be measured in a frequency range without adding new parts for calculating the AC impedance of the fuel cell to the fuel cell system or damaging the efficiency of the fuel cell system.

In addition, since the frequency of the current drawn from the fuel cell is controlled before the PCS (which generates power to be supplied to the load) is driven, the deterioration of the fuel cell may be diagnosed before the fuel cell system is normally operated. Accordingly, the deterioration of the fuel cell is diagnosed in no-load running or regular load running conditions before the fuel cell system is normally operated so that the deterioration of the fuel cell may be accurately diagnosed. Moreover, since the frequency of the current drawn from the fuel cell is controlled after the PCS is driven, the deterioration of the fuel cell may be diagnosed while the fuel cell system is normally operated. Accordingly, the deterioration of the fuel cell is diagnosed while the fuel cell system is normally operated and the operation of the fuel cell is stopped according to the result of diagnosis so that the fuel cell may be protected. Accordingly, the fuel cell may be prevented from breaking down or the life span of the fuel cell may be extended.

The all or a portion of the controller 160 or 460 for executing the methods described with reference to FIGS. 3 and 5 may be implemented using an array of a plurality of logic gates or a combination of general-use microprocessors and a recording medium having stored thereon a program to be executed in general-use microprocessors. In the latter case, the methods described with reference to FIGS. 3 and 5 may be written as computer programs and may be implemented in general-use digital computers that execute the programs using a computer readable recording medium. Examples of the computer readable recording medium include magnetic storage media (e.g., ROM, floppy disks, hard disks, etc.) and optical recording media (e.g., CD-ROMs, or DVDs).

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A method of diagnosing the deterioration of a fuel cell, the method comprising:
controlling a frequency of a current drawn from the fuel cell;
calculating an AC impedance of the fuel cell by using a pulse component of a current output from the fuel cell in response to the controlling of the frequency; and
diagnosing the deterioration of the fuel cell based on the calculated AC impedance.

2. The method of claim 1, wherein:
the controlling comprises changing the frequency to a frequency range, and
the calculating comprises calculating the AC impedance of the fuel cell in the frequency range.

3. The method of claim 2, wherein the calculating further comprises calculating the AC impedance of the fuel cell using a current value and a voltage value of the fuel cell measured at least one frequency in the frequency range.

4. The method of claim 3, wherein the calculating is repeated at sampling intervals for a fixed period of time.

5. The method of claim 1, wherein:
the controlling comprises controlling the frequency before driving a Power Conditioning System (PCS), which generates power to be supplied to a load, is driven, and
the diagnosing comprises comparing the calculated AC impedance with a threshold value used to diagnose the deterioration of the fuel cell in a no-load running condition and diagnosing the deterioration of the fuel cell based on a result of comparison.

6. The method of claim 1, wherein:
the controlling comprises controlling the frequency is controlled before driving the Power Conditioning System (PCS), which generates power to be supplied to a load, and
the diagnosing comprises comparing the calculated AC impedance with a threshold value used to diagnose the deterioration of the fuel cell in a regular load running mode and diagnosing the deterioration of the fuel cell based on a result of comparison.

7. The method of claim 1, wherein:
the controlling comprises controlling the frequency is controlled after driving the Power Conditioning System (PCS), which generates power to be supplied to a load, and
the diagnosing comprises comparing the calculated AC impedance with a threshold value used to diagnose the deterioration of the fuel cell in an arbitrary load running mode and diagnosing the deterioration of the fuel cell based on a result of comparison.

8. The method of claim 1, further comprising stopping the operation of the fuel cell according to a result of diagnosis for the deterioration of the fuel cell.

9. A computer readable recording medium having embodied thereon a computer program for executing a method of diagnosing the deterioration of a fuel cell performed by a computer, the method comprising:
controlling a frequency of a current drawn from the fuel cell;
calculating an AC impedance of the fuel cell by using a pulse component of a current output from the fuel cell that in response to the controlling of the frequency; and
diagnosing the deterioration of the fuel cell based on the calculated AC impedance.

10. An apparatus for diagnosing the deterioration of a fuel cell, the apparatus comprising:
a frequency controller which controls a frequency of a current drawn from the fuel cell;
an impedance calculation unit which calculates an AC impedance of the fuel cell using a pulse component of a current output from the fuel cell in response to the frequency controller controlling of the frequency; and
a state diagnosis unit which diagnoses the deterioration of the fuel cell based on the calculated AC impedance.

11. A fuel cell system comprising:
a fuel cell which generates power;
a controller which controls a frequency of a current drawn from the fuel cell and diagnoses the deterioration of the fuel cell using a pulse component of a current output from the fuel cell in response to the controlling of the frequency; and
a Power Conditioning System (PCS) which generates power to be supplied to a load from the power generated by the fuel cell.

12. The fuel cell system of claim 11, further comprising a converter which draws the current from the fuel cell according to the controlled frequency and converts a voltage of the drawn current.

13. The fuel cell system of claim 12, further comprising a Balance Of Plant (BOP) which operates the fuel cell, wherein the converter converts the voltage of the drawn current into a voltage required by the BOP.

14. The fuel cell system of claim 11, further comprising a heater which draws the current according to the controlled frequency and generates heat by using the drawn current.

15. The fuel cell system of claim 14, wherein the controller controls the frequency by controlling a switching frequency of a switch that is connected to the heater.
